(19) United States
(12) Patent Application Publication
(10) Pub. No.: US 2024/0213120 A1
(43) Pub. Date: Jun. 27, 2024

(54) MICRO-ELECTRONIC COMPONENT COMBINING POWER DELIVERY AND COOLING FROM THE BACK SIDE

(71) Applicant: IMEC vzw, Leuven (BE)

(72) Inventors: Herman Oprins, Herent (BE); Geert Van der Plas, Leuven (BE); Eric Beyne, Heverlee (BE); Pieter Woeltgens, Veldhoven (NL)

(21) Appl. No.: 18/393,221

(22) Filed: Dec. 21, 2023

(30) Foreign Application Priority Data
Dec. 22, 2022 (EP) 22216219.0

(51) Int. Cl. H01L 23/48; H01L 23/46; H01L 23/528; H01L 25/065

(52) U.S. Cl. CPC H01L 23/481; H01L 23/46; H01L 23/5283; H01L 25/0657

(57) ABSTRACT

A micro-electronic component, for example an integrated circuit chip, is provided. In one aspect, the component includes a front-end-of-line (FEOL) portion and a back-end-of-line (BEOL) portion at its front side. A back side power delivery network (PDN) is present at the back side of the component, with via connections connecting the PDN to the FEOL and BEOL portions. The back side PDN includes a “dry part” and a “wet part,” where the dry part includes multiple interconnect levels of the PDN embedded in a dielectric material. The “wet part” includes the remaining PDN levels which are not embedded in a dielectric but which are part of a manifold structure configured to receive therein a flow of cooling fluid in order to remove heat generated by the devices in the FEOL portion.

### CROSS-REFERENCE TO RELATED APPLICATIONS

This application claims foreign priority to European Patent Application No. EP 22216219.0, filed Dec. 22, 2022, which is incorporated by reference herein in its entirety.

### BACKGROUND

### Technological Field

The disclosed technology relates to micro-electronic components such as integrated circuit chips, and in particular to the cooling of such components.

### Description of the Related Technology

Integrated circuit chips and other semiconductor-based micro-electronic components can include a number of constituent parts, including a front end of line (FEOL) portion that includes a large number of semiconductor devices such as transistors and diodes processed on the front side of a semiconductor substrate according to a given layout. On top of the FEOL portion, the back end of line (BEOL) portion is processed, and can consist of a network of interconnected electrical conductors embedded in a dielectric material, and coupled to the devices in the FEOL, for providing signal routing into and out of the devices. In some IC designs, the BEOL portion also includes the power delivery network (PDN), that is, the conductors are configured to be coupled to a power supply voltage and a reference (usually ground) voltage for supplying power to the active devices in the FEOL.

As the number of devices on the chip increases, this conventional frontside PDN approach has created a competition in the BEOL between signal routing and power delivery, forcing trade-offs in terms of routing resources, as well as technology optimizations that can lead to compromises which are non-optimal for signals as well as for power.

For these and other reasons, designs were developed wherein the power delivery network was taken out of the BEOL and moved to the back side of the chip. This back side PDN comprises, like the front side BEOL, multiple interconnect levels which are now solely dedicated to the supply of power to the FEOL. The back side PDN can free up space on the front side for signal routing. An example back side PDN approach is described, for example, in EP Patent No. EP3324436.

A defining issue for any of these configurations, however, can be related to the cooling of the component. Heat is generated in the FEOL and can be removed to ensure device reliability. The main thermal concern with the back side PDN integration can be the higher self-heating due to the significantly thinned or even completely removed bulk substrate portion of the chip, and the increased presence of materials with low thermal conductivity (for example oxides) in the thermal path compared to conventional front side power delivery integration.

### SUMMARY OF CERTAIN INVENTIVE ASPECTS

It is an objective of the disclosed technology to provide a solution to the problems highlighted above. This and other aims can be achieved by micro-electronic components and methods in accordance with embodiments of the disclosed technology.

According to an aspect of the disclosed technology, a micro-electronic component, for example an integrated circuit chip, includes a FEOL portion and a BEOL portion at its front side. A back side PDN is also present at the back side of the component, with via connections connecting the PDN to the FEOL and BEOL portions at the front side. The back side PDN of a component according to the disclosed technology is different from prior designs, in that it includes a “dry part” and a “wet part”: the dry part includes multiple interconnect levels of the PDN which are closest to the FEOL portion. These levels are embedded in a dielectric material. The “wet part” includes the remaining PDN levels which are, however, not embedded in a dielectric but which are part of a manifold structure configured to receive therein a flow of cooling fluid in order to remove heat generated by the devices in the FEOL portion.

This configuration can enable more efficient cooling compared to conventional back side PDN designs by reducing the use of dielectric materials in the PDN, and by bringing the cooling fluid closer to the heat source, namely the active devices in the FEOL portion.

In an aspect of the disclosed technology, a micro-electronic component has a front side and a back side, and the component includes:
at the front side of the component, a front end of line (FEOL) portion including a plurality of semiconductor devices, and on the FEOL portion, a back end of line (BEOL) portion including multiple interconnect levels,
at the back side of the component, a power delivery network (PDN) including multiple interconnect levels, and power supply terminals electrically connected to the upper interconnect level, and
a plurality of via connections for electrically connecting the semiconductor devices to the power delivery network, wherein
the first and a number of subsequent levels of the PDN are formed of electrical conductors embedded in a dielectric material, and
at least the two upper levels of the PDN include electrical conductors which are part of a manifold structure configured to receive therein a flow of cooling fluid flowing into and out of the manifold structure, in order to remove heat generated by the devices in the FEOL portion.

According to an embodiment, the manifold structure includes an input port and an output port configured to direct respective input and output flows in a direction that is oriented essentially perpendicularly to the back to front direction of the component.

According to an embodiment:
the at least two upper levels of the PDN each include an array of parallel line-shaped conductors interconnected by via connections, so that the spacing between each pair of parallel conductors forms a fluid channel and wherein the conductors of each pair of adjacent levels are arranged in crosswise fashion, so that a cooling fluid is able to flow from one level to an adjacent level and back, and
the manifold structure further includes guiding elements for guiding a cooling fluid towards and away from the at least two upper levels of conductors.

According to an embodiment, the guiding elements include a floor portion at the same level as at least the lowest level of parallel conductors, a wall portion on the floor portion including wall elements which define a flow path for cooling fluid towards and from the conductors of one or more upper levels, and a cover on the wall portion.

According to an embodiment, the input and output ports are at the same level as the upper level of conductors of the manifold structure, and the guiding elements are configured so that a cooling fluid flowing from the inlet port to the outlet port is forced to flow between first selected pairs of upper-level conductors, thereafter downwards between conductors of one or more lower levels and again upwards so as to flow towards the outlet port between second selected pairs of upper-level conductors.

According to an embodiment, the guiding elements are formed of a non-electrically conductive material.

According to an embodiment, the guiding elements are formed of an electrically conductive material and an electrically non-conductive material separates the parallel conductors from the guiding elements.

According to an embodiment, the contact terminals are realized in the form of contact pads on the upper surface of the conductors of the upper level of the manifold structure.

According to an embodiment, the guiding elements include a cover and the cover is provided with openings for allowing the passage of the contact pads.

According to an embodiment, the electrical conductors of the PDN embedded in a dielectric material include crosswise arranged levels of line-shaped electrical conductors interconnected by via connections, wherein the density of the via connections is between 10% and 50%.

In another aspect of the disclosed technology, a method for producing a component includes the following steps:
producing the front end of line portion on the front side of a semiconductor substrate,
producing the back end of line portion on the front end of line portion,
thereafter, attaching the front side of the substrate to a carrier,
thereafter, thinning or removing the substrate from the back side,
thereafter, producing a plurality of levels of the back side PDN, the plurality of levels being embedded in a dielectric material, this step ending with the production of a planar hybrid surface formed of the dielectric material with patches of a conductive material coplanar with the dielectric material, and
producing the manifold structure on the planar hybrid surface, wherein the levels of the PDN included in the manifold structure are contacting the patches of conductive material on the hybrid surface.

According to an embodiment of the method, the manifold structure is produced by one or more 3D printing steps.

According to an embodiment of the method, the at least two upper levels each include an array of parallel line-shaped conductors, so that the spacing between each pair of parallel conductors forms a fluid channel and the conductors of each pair of adjacent levels are arranged in crosswise fashion, so that a cooling fluid is able to flow from one level to an adjacent level and back, the manifold structure further including guiding elements for guiding a cooling fluid towards and away from the at least two upper levels of conductors, wherein:
the conductors of the at least two upper levels are produced on the hybrid surface by a first 3D printing step,
at least some of the guiding elements are produced on the hybrid surface by a second 3D printing step.

The method may further include the step of depositing a non-electrically conductive layer on all exposed surfaces of electrical conductors of the PDN which are part of the manifold structure.

The disclosed technology is equally related to a stack of interconnected semiconductor chips, wherein the upper chip is a component in accordance with the disclosed technology and wherein the manifold structure and the terminals are oriented upwards so as to allow the supply of power to the stack via the terminals.

### BRIEF DESCRIPTION OF THE DRAWINGS

FIG. 1 illustrates an integrated circuit chip in accordance with an embodiment of the disclosed technology.

FIGS. 2A and 2B are two section views according to two orthogonal section planes of a portion of the chip shown in FIG. 1.

FIGS. 3 and 4 present 3D views taken from upper and lower viewpoints of the manifold structure included in the chip shown in FIG. 1, with the cover removed.

FIG. 5 is a 3D view of the manifold structure including the cover.

FIG. 6 is a further enlargement of a portion of the section view shown in FIG. 2A, illustrating the constituent layers of the “dry part” of the chip.

FIG. 7 is an additional enlargement of a portion of the section view indicated in FIG. 6, illustrating the structure of the FEOL portion and of the “dry part” of the backside PDN.

FIGS. 8A to 8C illustrate the capabilities of a chip according to the disclosed technology when applied in a 3D logic/memory configuration.

### DETAILED DESCRIPTION OF CERTAIN ILLUSTRATIVE EMBODIMENTS

In the following detailed description, any reference to dimensions and materials is made by way of example only and does not limit the scope of the disclosed technology.

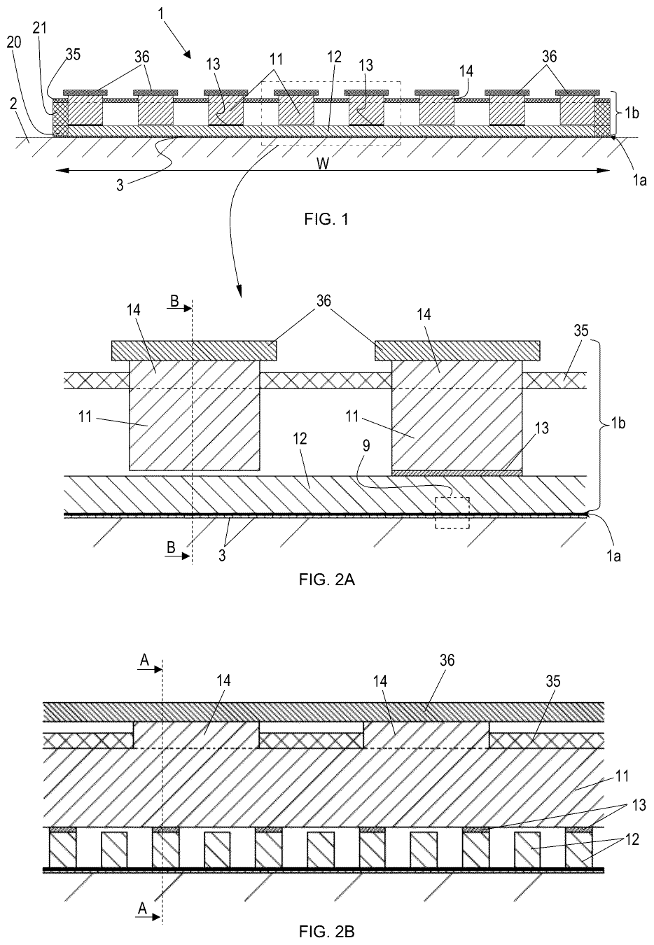

FIG. 1 shows a cross-section of an integrated circuit chip 1 in accordance with an embodiment of the disclosed technology. The chip has a rectangular shape with a width W of about 5 mm. The length of the chip in the direction perpendicular to the section view in FIG. 1 is longer than the width W, as will become apparent later. The chip may nevertheless be square instead of rectangular, and it may be larger than in the illustrated example. The dimensions and shape of the chip are not limited to specific values or forms.

The chip 1 is mounted on a carrier 2, which may be a printed circuit board or an interposer chip, by way of solder bump connections 3. The chip 1 may, however, also be part of a 3D stack, that is, it may be stacked on top of another chip of the same or comparable size. As described above, the chip 1 is divided in a “dry part” 1a and a “wet part” 1b, the latter corresponding mainly to a manifold structure configured to enable the passage of a cooling fluid. Details and constituent layers of the “dry part” 1a are not discernible in FIG. 1 and will be described later with reference to various enlarged images. The fact that electrical conductors incorporated in the manifold structure are part of a back side power delivery network of the chip 1 will also become apparent from the description of the “dry part” 1a and the manner in which it is connected to the “wet part” 1b.

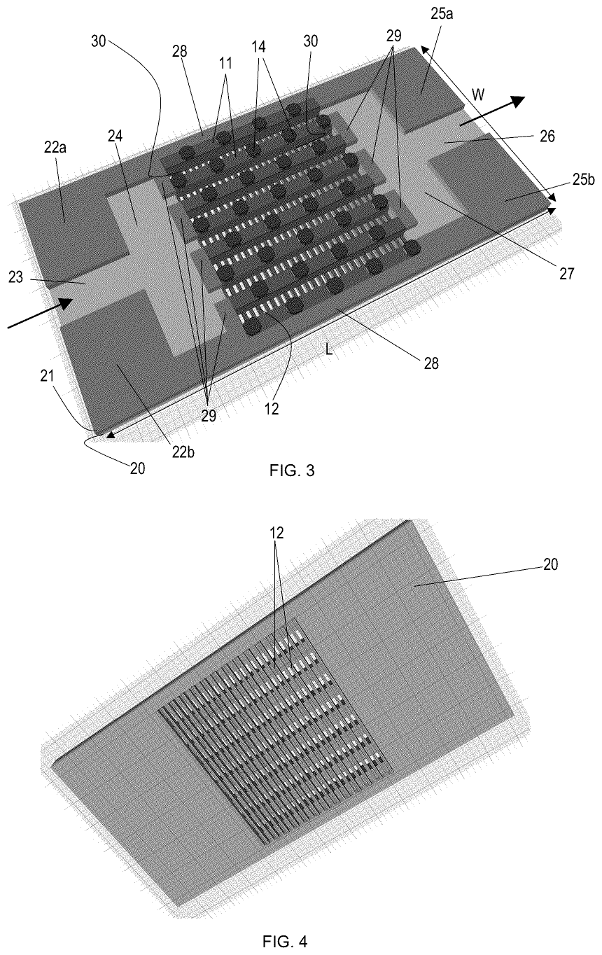

Before going into these aspects however, the manifold structure as such is first described, with reference to FIG. 1, the enlarged images in FIGS. 2A and 2B, and the 3D images in FIGS. 3 to 5. It is emphasized that the structure presented in these images is just one possible form of the manifold structure and that the disclosed technology is not limited to this particular form.

In FIGS. 1, 2A and 2B, it is seen that the manifold structure includes two levels of electrical conductors, an upper level including an array of parallel conductors 11 and a lower level including an array of parallel conductors 12. The conductors of the two levels are arranged crosswise relative to each other and are interconnected by via connections 13. The combined height of the two levels is in the order of 300 μm. The upper level includes eight conductors 11, each provided with cylinder-shaped and regularly spaced contact pads 14 on their upper surface, the contact pads 14 being integrally formed with the upper-level conductors 11. The lower level includes a higher number of more narrow and more closely spaced conductors 12. The number of conductors in the upper and lower levels may be much higher and has been kept deliberately low in the illustrated embodiment in order not to complicate the drawings.

In the 3D images shown in FIGS. 3 and 4, and also in the cross section in FIG. 1, it is seen that the manifold structure further include guide elements for guiding a cooling fluid towards and away from the two levels of conductors 11 and 12. In the particular embodiment shown, these guide elements include a floor portion 20 and a wall portion 21 on top of the floor portion 20. In some embodiments, these portions are part of an integrally formed piece formed of a single material, but they are described here separately in order to clarify the functionality of these elements and their constituent parts. It can be seen in FIGS. 3 and 4 that the chip has a rectangular shape with the length L larger than the width W already referred to above in relation to the section shown in FIG. 1.

As shown in FIG. 4, the floor portion 20 is closely fitted around the conductors 12 of the lower level and its height is about equal to the height of the lower-level conductors 12. In this description, the wording “closely fitted” and “closely fitting” when applied to adjacent components or surfaces indicates a proximity that realizes an effective seal between the adjacent components, when applied in combination with a suitable cooling fluid.

The wall portion 21 include wall elements which define a flow path of cooling fluid towards and from the upper-level conductors 11. The wall elements include on the inlet side a pair of sidewalls 22a and 22b for defining an inlet port 23 and an inlet collector area 24, and likewise on the outlet side sidewalls 25a and 25b for defining an outlet port 26 and an outlet collector area 27. The wall portion 21 further include sidewalls 28 closely fitting against the sidewalls of the outer conductors 11 of the upper level, and blocking elements 29 closely fitting the outer ends of selected upper-level conductors 11, so as to create channels 30 which are in fluid communication with the inlet and outlet collector areas 24 and 27. The flow direction of a cooling fluid into and out of the manifold structure, as indicated by two arrows, is oriented perpendicularly to the chip in the embodiment shown. Embodiments of the disclosed technology are, however, not limited to manifold structures which require this flow direction.

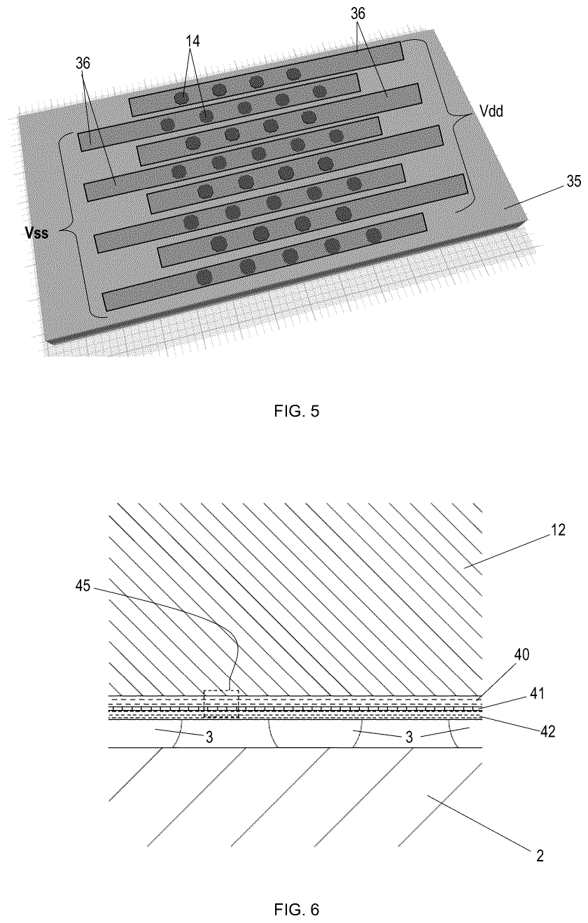

In order for the manifold structure to be able to conduct a flow of cooling fluid from the inlet port 23 to the outlet port 26, a cover 35 is mounted on the wall portion 21, as seen in FIGS. 1, 2A, 2B, and 5. The cover 35 is therefore also a flow guiding element, like the portions 20 and 21. Holes are provided in the cover 35 for allowing the passage of the contact pads 14, with the cover closely fitting around the contact pads. As seen in FIG. 5 and also in FIGS. 1, 2A, and 2B, contact leads 36 are connected to the rows of contact pads 14 protruding through the cover 35, for supplying power to the chip 1. The rectangles 36 in FIG. 5 are merely intended to indicate the approximate position of the leads, and they are also shown in transparent view, so that the locations of the pads 14 are visible. The contact leads 36 are also not necessarily a part of the chip 1 when it is obtained as a finished product. A first set of four leads 36 are coupled to a supply voltage marked by the conventional notation Vdd, while a second set of four leads 36 are coupled to a reference voltage, conventionally marked as Vss (usually this is the ground potential). The upper-level conductors 11 are thereby alternately connected to Vdd and Vss. The via connections 13 between the upper and lower-level conductors are arranged so that also the lower-level conductors 12 are alternately connected to these two voltages.

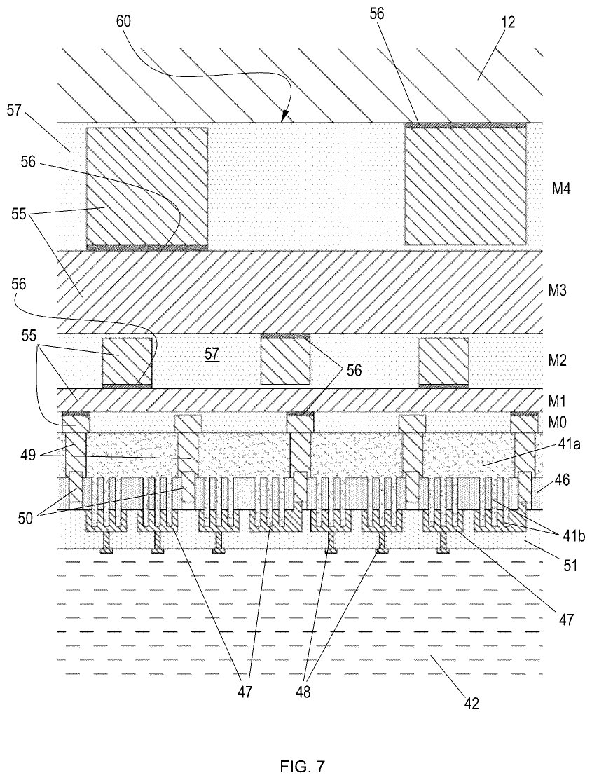

Below the lower-level conductors 12 are additional levels of the back side PDN which belong to the “dry part” of the chip, described now in more detail with reference to the enlarged images shown in FIGS. 6 and 7. FIG. 6 is an enlarged view of the rectangle 9 indicated in FIG. 2A. Three distinct layers extend between the lower-level conductors 12 of the manifold structure and the solder bumps 3. The first layer 40 having a thickness in the order of 2.5 μm consists of the additional PDN levels. The second layer 41 is formed of a semiconductor substrate of less than 1 μm thick, with its front side oriented downward, that is, the PDN is located on the back side of the substrate. On the front side of this substrate 41 is a plurality of active devices, which are not discernible on the scale of the image of FIG. 6. These devices form the front end of line portion of the chip 1. These devices are connected to the solder bumps 3 through the multiple interconnected levels of the back end of line portion that forms the third layer 42, and which may also have a thickness in the order of a few m.

A final enlargement of the rectangle 45 indicated in FIG. 6 shows these constituent layers in more detail, in FIG. 7, for one example of an applicable FEOL/BEOL/backside PDN structure according to the disclosed technology. The image is conceptual rather than aimed at presenting a realistic structure. The BEOL portion 42 is not represented in detail. The substrate 41 is shown in more detail, and is seen to include a bulk portion 41a and a plurality of nano-sized fins 41b integral with the bulk portion 41a and separated by oxide regions 46, commonly referred to as shallow trench isolation (STI) regions. Epitaxially grown contact areas 47 are represented as well, which may define for example source or drain areas of MOSFETs processed on the fins 41b. Some of the contact areas are coupled to the BEOL portion 42 through via connections 48 through a dielectric layer 51, while others are connected to a plurality of so-called “through semiconductor via” connections (TSVs) 49 through a plurality of buried power rails 50. TSVs are via connections which pass through a bulk semiconductor substrate for connecting the front side of the substrate to the back side thereof. In most cases, these TSVs are separated from the semiconductor material by a dielectric liner (not shown in the drawing). In the disclosed technology, the term “via connection” is used as a generic term for designating any vertical via connection, that is, either a TSV or a via connection through a dielectric material. The disclosed technology is not limited to micro-electronic components including a bulk semiconductor substrate 41a and TSVs, as will be describe below. This configuration is merely used as an example for explaining how the “wet part” of the component is coupled to the “dry part.”

The TSVs 49 are connected to the first five levels M0 to M4 of the backside PDN. Like the two levels of the “wet part,” these “dry” levels include multiple conductors 55 arranged in crosswise fashion and interconnected by via connections 56, wherein the dimensions of the conductors 55 increase from M0 to M1.

In contrast to the “wet” PDN levels, the dry levels are embedded in a dielectric material 57, for example SiO₂ or a high-K dielectric. The upper surface of the “dry part” is a planar hybrid surface 60, that is, a surface including mainly dielectric material with patches of metal coplanar with the dielectric, the patches forming the top surfaces of via connections 56. On this level hybrid surface 60, the manifold structure described above is positioned so that the lower-level conductors 12 of the manifold structure contact the via connections 56 on the hybrid surface 60. The “dry” levels of the backside PDN are interconnected by the respective via connections 56 in such a manner that the supply voltage

Vdd and the reference voltage Vss are effectively transferred through the subsequent levels, down to the active devices in the FEOL portion, for the purpose of supplying power to these devices. The conductors 11 and 12 of the manifold structure thus form levels M5 and M6 of the backside PDN.

In operation, the chip 1 is cooled by supplying a cooling fluid to the inlet port 23 of the manifold structure. The fluid flows through the three channels 30 between the upper conductors 11 which are not blocked by blocking elements 29 at the inlet side. As these channels are however blocked on the outlet side, the fluid is forced to flow between the conductors 12 of the lower level, emerging back upwards in the four upper channels 30 which are in fluid communication with the outlet port 26. This flow pattern thereby forces the cold fluid entering through the inlet port 23 to flow along the hybrid dielectric/metal surface 60 of the “dry part,” where it takes up heat produced by the devices in the FEOL, subsequently evacuating the heat by flowing out through the outlet port 26.

In some embodiments, the cooling manifold is further combined with an optimized design of the “dry part” in terms of the density and height of the via connections 56 in this dry part. By maximizing the via density and minimizing the height, thermal conductivity in the vertical direction across this “dry part” can be optimized. According to some embodiments, the via density in the dry part is between 10% and 50%. According to further embodiments, the via density is between 20% and 50%, or between 30% and 50%, or between 40% and 50%. The height of the vias 56 (in all the “dry” levels) can be as low as realistically attainable with the applied fabrication method (for example a single or double damascene processing technique). A via height between 5-50 nm or between 5 nm and 100 nm is, for example, applicable according to embodiments of the disclosed technology.

Producing a chip or other component according to the disclosed technology can start with a number of process steps which can be suitably implemented and which will only be briefly summarized hereafter, for the case of producing the chip 1 shown in FIGS. 1 to 7. The front end of line portion is first processed on the front side of a standard process wafer, which may be for example a 300 mm diameter monocrystalline silicon wafer or a silicon-on-insulator wafer. Then the BEOL portion 42 is produced on the FEOL portion using any suitable technique, for example by damascene-type processing. The wafer is then flipped and temporarily bonded to a carrier substrate, and subsequently thinned from the backside by grinding and planarization techniques such as chemical mechanical polishing (CMP). The final very reduced thickness of the bulk substrate portion 41a can be obtained by wet etching, possibly stopping on an etch stop layer incorporated in the wafer. Then TSV openings may be formed by lithography and etching, followed by filling the openings with a dielectric liner and a metal (so-called “TSV last” approach). However, it is also possible to form the TSVs prior to processing the FEOL portion, and to thin the wafer until the pre-formed TSVs are exposed (a “TSV first” approach). Following this, the first five PDN levels M0 to M4 are processed, for example by damascene-type processing. The processing of the “dry part” ends with the production of the planar hybrid dielectric/metal surface 60 onto which the manifold structure is to be formed.

As stated earlier, embodiments of the disclosed technology are not limited to a configuration including TSV connections through a thin bulk substrate portion 41a as illustrated in FIG. 7. The disclosed technology is equally applicable to an integrated circuit chip wherein no bulk substrate portion is left, that is, the bulk of the substrate onto which fin-shaped Si-based devices or nano-sheet devices have been processed is completely removed from the back side and the connection to the back side PDN is realized by via connections through the STI material. The “dry part” of the backside PDN is then produced on the revealed surface of this STI, that is, directly on the back side of the FEOL portion, in the manner described above, that is, by building for example layers M0 to M4, and stopping when the hybrid surface 60 is formed.

For this reason, in embodiments of the disclosed technology, the FEOL and BEOL portions are described as located “at the front side of the component,” and the PDN is described as located “at the back side of the component.” This can thus either mean that these layers are formed respectively on the front and back side of a bulk semiconductor substrate 41a, or that the PDN is formed directly on the back side of the FEOL portion.

The manifold structure can be obtained by a variety of techniques. The structure may, for example, be produced by one or more 3D printing steps. According to one embodiment of the disclosed technology, two printing steps are applied to produce the structure shown in FIG. 3. First the two-level conductor structure including conductors 11 and 12 and via connections 13 is formed, using an electrically conductive material, for example aluminum.

On the planar hybrid surface 60 referred to above, the aluminum is printed layer by layer, in accordance with a predefined scheme in terms of the positions of the lower and upper-level conductors 12 and 11 and the via connections 13. The contact pads 14 on the upper conductors 11 are formed in the same step. Then the surrounding floor and wall portions 20 and 21 are formed around the conductors 11 and 12 by a second 3D printing step, using a non-conducting, for example plastic or ceramic, material that is able to withstand the applicable temperatures in the manifold structure, which may be up to 100° C. One example of a suitable 3D-printable non-electrically conducting plastic material is the material Somos® perFORM from DSM.

Alternatively, a single 3D printing step may be performed, using two different materials in the respective predefined areas for the conductors Nov. 12, 2013 (for example, metal) and the floor and wall portions 20/21 (for example, insulating material).

The cover 35 may equally be formed by continued 3D printing above the level of the wall portion 21. This can be performed using any suitable printing technique that enables the formation of cavities, for example by printing layers in a given area and illuminating the material down to a given depth in order to change the material from solid to liquid or vice versa, so that unwanted material can be removed from the inside of a cavity after the printing and illumination steps.

Alternatively, the cover 35 may be formed by a separate 3D printing step or by another manufacturing method, in the form of a plate provided with holes at the positions of the contact pads 14. The cover may then be assembled to the wall portion 21 by fitting it over the contact pads 14 and attaching it to the upper surface of the wall portion 21 by a watertight adhesive.

According to yet another alternative according to the disclosed technology, the two-level conductor structure Nov. 12, 2013, the floor and wall portions 20/21 may be formed simultaneously in a single 3D printing step, using the same electrically conductive material, for example aluminum for the conductors as well as for the floor and wall portions and possibly the cover, but applying an isolation layer between adjacent parts of the conductors and the floor and wall portions.

The cover 35 could also be formed of metal. In that case however, an isolation layer can be applied on the upper conductors 11 and on the sidewalls of the contact pads 14, for isolating these components from the cover 35.

Another way of obtaining the manifold structure could be to form the two-level conductor structure Nov. 12, 2013 by milling a rectangular piece of metal such as aluminum, and bonding the structure to the hybrid dielectric/metal surface 60 of the dry part. The floor and wall portions 20/21 could then again be formed by 3D printing.

All of the above-described process steps can be performed on the wafer level, that is, before the process wafer is separated into separate chips and/or other components. The finished chip 1 may then be released from the carrier and bonded to a PCB or interposer in the manner illustrated in FIG. 1.

In some prior configurations including a back side PDN, the carrier may be maintained in the final chip (for example, separate the carrier also by dicing), in order to provide sufficient mechanical stability to the chip. In embodiments of a chip according to the disclosed technology, the manifold structure can be much thicker than the FEOL/BEOL and “dry” PDN part combined, so that this manifold structure lends mechanical stability to the chip. A carrier on the opposite side may therefore be omitted.

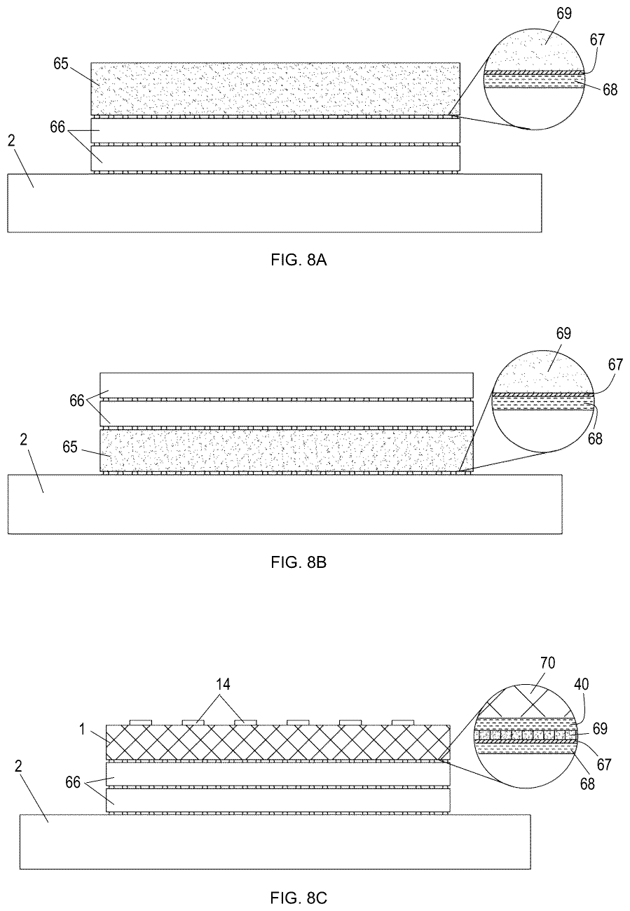

The disclosed technology is also applicable to a chip bonded to one or more other chips in a 3D chip stacking technology. Here the advantages of embodiments of the disclosed technology are especially apparent. This is explained using some example configurations shown in FIGS. 8A to 8C. FIG. 8A is a first prior art configuration of a stack of interconnected chips bonded to a PCB 2. The stack includes a logic chip 65 and two memory chips 66. The logic chip 65 includes a FEOL portion 67 and a BEOL portion 68 on the front side of a semiconductor substrate portion 69 of the chip, with the power delivery network incorporated in the BEOL portion 68. The logic chip 65 is bonded face down to the stack of memory chips 66. In this configuration, power is supplied from the PCB 2 to the logic chip 65, which requires dedicated power supply pins on all of the memory chips 66. This means that the power delivery will be severely constrained by (i) the resistance of the connections through the memory chips 66 as well as (ii) the competition in use of the available 3D vertical interconnections for power supply of the logic chip 65 and for signal connectivity across the 3D chip stack. Cooling this stack can be done by cooling the back side of the logic chip 65. As the thermal conductivity of the substrate 69 is relatively high, and there are essentially no thermally insulating materials between the FEOL portion 67 and the back of the chip, cooling this configuration can therefore be relatively easy.

FIG. 8B illustrates a second prior art configuration. The logic chip 65 is now bonded directly to the PCB, that is, the front side PDN contacts the PCB and the memory chips are stacked on top of the logic chip 65. The FEOL and BEOL portions 67 and 68 are indicated as well. Via connections (not shown) through the substrate 69 connect the logic chip 65 to the memory chips 66.

In the configuration of FIG. 8B, a much more direct, lower resistance power supply of the logic chip can be accomplished, but there still is competition in the use of 3D interconnects between the logic chip 65 and the PCB 2 for power on one hand and signaling on the other. Furthermore, cooling the logic chip 65 can be more difficult because it is now at the bottom of the stack, with the memory chips 66 in between the logic chip and a heat sink.

The image in FIG. 8C illustrates a configuration that is enabled by embodiments of the disclosed technology, at the same time optimizing cooling, power delivery and availability of signal interconnects across the 3D chip stack. The logic chip 1 is in accordance with the disclosed technology and may be realized as shown in FIG. 1 or according to any other embodiment of the disclosed technology. The thinned semiconductor substrate 69, and the FEOL and BEOL portions 67 and 68 are again indicated. The “dry part” of the back side PDN is indicated and referenced by the same numeral 40 as in the previous parts of the description. The “wet part” 70 of the back side PDN, including a manifold structure as described above or according to any other embodiment of the disclosed technology is not shown in detail, apart from a number of power supply terminals 14. The logic chip 1 is placed at the top of the stack with the “wet part” oriented upwards. Power is supplied therefore to the top of the stack, to the terminals 14, while the stack is cooled from the top side by supplying a cooling fluid to the manifold structure. This configuration enables (i) optimized cooling capability, (ii) optimized power delivery to the logic chip, and (iii) high availability of connection across the 3D chip stack for signaling.

The cooling fluid applied when the chip is operational may be water or any other suitable fluid in the liquid or gaseous state. The fluid may be electrically conductive or non-conductive. In the case of electrically conductive fluid, an isolation layer can be applied on all the surfaces of the conductors 11 and 12 and the via connections 13 that are exposed to the fluid. One way of applying such a layer is by a technique applicable, for example, on a manifold structure wherein the conductors 11 and 12 are formed of aluminum. According to this technique, an alkaline solution is supplied to the finished manifold structure, that is, flowing from the inlet port to the outlet port, followed by a supply of boiling demineralized water or steam, resulting in the deposition of an aluminum oxide layer on all of the exposed aluminum surfaces. The alkaline solution removes native oxides from the aluminum. The treatment with water or steam results in the controlled formation of an aluminum oxide layer that will isolate the conductors electrically. An example of this technique is described in Din et al., “Accelerated growth of oxide film on aluminium alloys under steam: Part II: Effects of alloy chemistry and steam vapour pressure on corrosion and adhesion performance,” Surface and Coatings Technology, Volume 276, August 2015, pages 106-115.

However, if no such oxide layer has been deposited, the manifold structure can be used in combination with any suitable non-electrically conductive cooling fluid.

As already indicated, the disclosed technology is not limited to the specific manifold structure illustrated in the drawings. The number of PDN levels incorporated in the manifold structure could be higher than 2, for example. The inlet and outlet ports could be arranged differently from the illustrated embodiment, for example oriented at right angles relative to each other and placed at the level of different PDN levels. The fluid could also enter the chip vertically through an opening in the cover 35, and flow out of the component vertically as well, or a combination of different in and outflow directions could be applied.

While embodiments of the disclosed technology have been illustrated and described in detail in the drawings and foregoing description, such illustration and description are to be considered illustrative or exemplary and not restrictive. Other variations to the disclosed embodiments can be understood and effected by those skilled in the art in practicing the disclosed technology. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

What is claimed is:

1. A micro-electronic component having a front side and a back side, the component comprising:
at the front side of the component, a front end of line (FEOL) portion comprising a plurality of semiconductor devices, and, on the FEOL portion, a back end of line (BEOL) portion comprising multiple interconnect levels;
at the back side of the component, a power delivery network (PDN) comprising multiple interconnect levels, and power supply terminals electrically connected to the upper interconnect level; and
a plurality of via connections for electrically connecting the semiconductor devices to the power delivery network, wherein the first and a number of subsequent levels of the PDN are formed of electrical conductors embedded in a dielectric material, and
at least the two upper levels of the PDN include electrical conductors which are part of a manifold structure configured to receive therein a flow of cooling fluid flowing into and out of the manifold structure, in order to remove heat generated by the plurality of semiconductor devices in the FEOL portion.

2. The component according to claim 1, wherein the manifold structure comprises an input port and an output port configured to direct respective input and output flows in a direction that is oriented essentially perpendicularly to the back to front direction of the component.

3. The component according to claim 1, wherein:
the at least two upper levels of the PDN each comprise an array of parallel line-shaped conductors interconnected by via connections, so that the spacing between each pair of parallel conductors forms a fluid channel,
the conductors of each pair of adjacent levels are arranged in crosswise fashion, so that a cooling fluid is able to flow from one level to an adjacent level and back, and
the manifold structure further comprises guiding elements configured to guide a cooling fluid towards and away from the at least two upper levels of conductors.

4. The component according to claim 3, wherein the guiding elements include a floor portion at the same level as at least the lowest level of parallel conductors, a wall portion on the floor portion comprising wall elements which define a flow path for cooling fluid towards and from the conductors of one or more upper levels, and a cover on the wall portion.

5. The component according to claim 3, wherein the input and output ports are at the same level as the upper level of conductors of the manifold structure, and wherein the guiding elements are configured so that a cooling fluid flowing from the inlet port to the outlet port is forced to flow between first selected pairs of upper-level conductors, thereafter downwards between conductors of one or more lower levels and again upwards so as to flow towards the outlet port between second selected pairs of upper-level conductors.

6. The component according to claim 3, wherein the guiding elements are formed of a non-electrically conductive material.

7. The component according to claim 3, wherein the guiding elements are formed of an electrically conductive material, and wherein an electrically non-conductive material separates the parallel conductors from the guiding elements.

8. The component according to claim 3, wherein the contact terminals comprise contact pads on the upper surface of the conductors of the upper level of the manifold structure.

9. The component according to claim 8, wherein the guiding elements include a cover, and wherein the cover is provided with openings configured to allow the passage of the contact pads.

10. The component according to claim 1, wherein the electrical conductors of the PDN embedded in a dielectric material include crosswise arranged levels of line-shaped electrical conductors interconnected by via connections, and wherein the density of the via connections is between 10% and 50%.

11. A method of producing a component according to claim 1, comprising:
producing the front end of line (FEOL) portion on the front side of a semiconductor substrate;
producing the back end of line (BEOL) portion on the front end of line portion;
thereafter, attaching the front side of the substrate to a carrier;
thereafter, thinning or removing the substrate from the back side;
thereafter, producing a plurality of levels of the back side PDN, the plurality of levels being embedded in a dielectric material, then producing a planar hybrid surface formed of the dielectric material with patches of a conductive material coplanar with the dielectric material; and
producing the manifold structure on the planar hybrid surface, wherein the levels of the PDN included in the manifold structure are contacting the patches of conductive material on the hybrid surface.

12. The method according to claim 11, wherein the manifold structure is produced by one or more 3D printing steps.

13. The method according to claim 11, wherein the at least two upper levels of the PDN each comprise an array of parallel line-shaped conductors, so that the spacing between each pair of parallel conductors forms a fluid channel, wherein the conductors of each pair of adjacent levels are arranged in crosswise fashion, so that a cooling fluid is able to flow from one level to an adjacent level and back, the manifold structure further comprising guiding elements for guiding a cooling fluid towards and away from the at least two upper levels of conductors, and wherein
the conductors of the at least two upper levels are produced on the hybrid surface by a first 3D printing step, and
at least some of the guiding elements are produced on the hybrid surface by a second 3D printing step.

14. The method according to claim 11, further comprising depositing a non-electrically conductive layer on all exposed surfaces of electrical conductors of the PDN which are part of the manifold structure.

15. A stack of interconnected semiconductor chips, wherein the upper chip is a component in accordance with claim 1, and wherein the manifold structure and the power supply terminals are oriented upwards so as to allow the supply of power to the stack via the power supply terminals.
